(19) United States
(12) Patent Application Publication
(10) Pub. No.: US 2026/0363128 A1
(43) Pub. Date: Nov. 12, 2026

(54) SEMICONDUCTOR DEVICE

(71) Applicant: ROHM CO., LTD., Kyoto-shi (JP)

(72) Inventor: Kazuki HASHIMOTO, Kyoto-shi (JP)

(21) Appl. No.: 19/715,487

(22) Filed: Jun. 22, 2026

Related U.S. Application Data
(63) Continuation of application No. PCT/JP2024/043170, filed on Dec. 6, 2024.

(30) Foreign Application Priority Data
Dec. 27, 2023 (JP) 2023-220510

(51) Int. Cl. H10W 72/60; H10W 70/40; H10W 74/10; H10W 90/00

(52) U.S. Cl. CPC H10W 72/627; H10W 70/481; H10W 72/634; H10W 74/129; H10W 90/736; H10W 90/756; H10W 90/766

(57) ABSTRACT

A semiconductor device includes: a semiconductor element including an element body, a first electrode, and a second electrode; a first lead located on a first side in a second direction intersecting a first direction relative to the semiconductor element; a second lead including a second terminal surface located on a second side in the second direction relative to the first lead; a first conductive member extending from the semiconductor element to the first side in the second direction, and electrically connecting the first electrode and the first lead; a second conductive member extending from the semiconductor element to the first side in the second direction, and electrically connecting the second electrode and the second lead; and a sealing resin covering the semiconductor element, the first conductive member, the second conductive member, and parts of the first lead and the second lead, while exposing a first terminal surface and a second terminal surface.

### TECHNICAL FIELD

The present disclosure relates to a semiconductor device.

### BACKGROUND ART

JP-A-2023-73509 discloses an example of a conventional semiconductor device. The semiconductor device disclosed in this document includes a semiconductor element and a plurality of leads. The leads are located on opposite sides with the semiconductor element therebetween. The semiconductor element and the leads are connected via a plurality of bonding wires.

### BRIEF DESCRIPTION OF THE DRAWINGS

FIG. 1 is a perspective view showing a semiconductor device according to a first embodiment of the present disclosure.

FIG. 2 is a perspective view showing the semiconductor device according to the first embodiment of the present disclosure.

FIG. 3 is a partial plan view showing the semiconductor device according to the first embodiment of the present disclosure.

FIG. 4 is a bottom view showing the semiconductor device according to the first embodiment of the present disclosure.

FIG. 5 is a cross-sectional view along line V-V in FIG. 3.

FIG. 6 is a cross-sectional view along line VI-VI in FIG. 3.

FIG. 7 is a cross-sectional view along line VII-VII in FIG. 3.

FIG. 8 is a cross-sectional view along line VIII-VIII in FIG. 3.

FIG. 9 is a cross-sectional view showing a first variation of the semiconductor device according to the first embodiment of the present disclosure.

FIG. 10 is a partial plan view showing a second variation of the semiconductor device according to the first embodiment of the present disclosure.

FIG. 11 is a partial plan view showing a third variation of the semiconductor device according to the first embodiment of the present disclosure.

FIG. 12 is a cross-sectional view along line XII-XII in FIG. 11.

FIG. 13 is a cross-sectional view along line XIII-XIII in FIG. 11.

FIG. 14 is a perspective view showing a semiconductor device according to a second embodiment of the present disclosure.

FIG. 15 is a perspective view showing the semiconductor device according to the second embodiment of the present disclosure.

FIG. 16 is a partial plan view showing the semiconductor device according to the second embodiment of the present disclosure.

FIG. 17 is a bottom view showing the semiconductor device according to the second embodiment of the present disclosure.

FIG. 18 is a cross-sectional view along line XVIII-XVIII in FIG. 16.

FIG. 19 is a cross-sectional view along line XIX-XIX in FIG. 16.

FIG. 20 is a cross-sectional view along line XX-XX in FIG. 16.

FIG. 21 is a cross-sectional view along line XXI-XXI in FIG. 16.

FIG. 22 is a cross-sectional view showing a first variation of the semiconductor device according to the second embodiment of the present disclosure.

### DETAILED DESCRIPTION OF EMBODIMENTS

The following describes preferred embodiments of the present disclosure in detail with reference to the drawings.

The terms such as “first”, “second” and “third” in the present disclosure are used merely for identification, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”. Further, the phrase “a plane A faces (a first side or a second side) in a direction B” is not limited to the case where the angle of the plane A with respect to the direction B is 90°, but also includes the case where the plane A is inclined to the direction B.

### First Embodiment

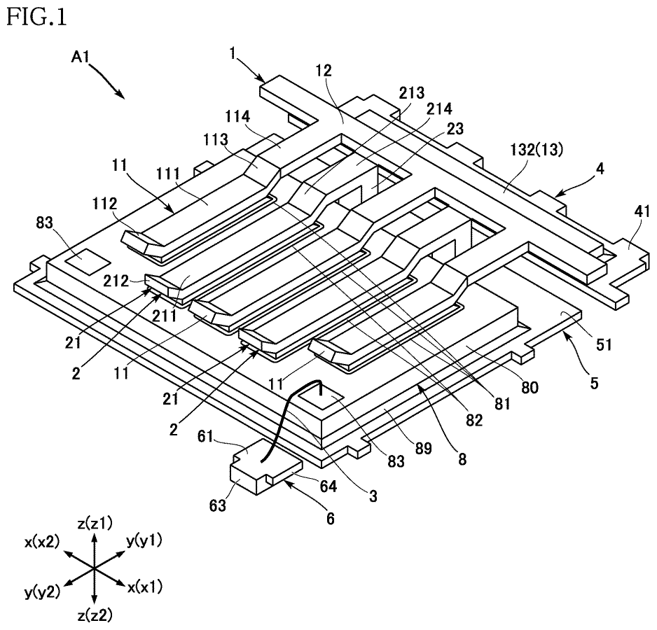

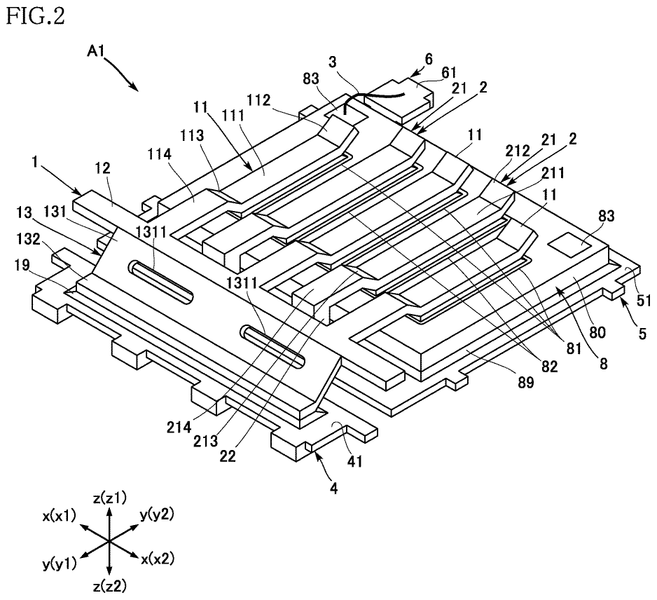

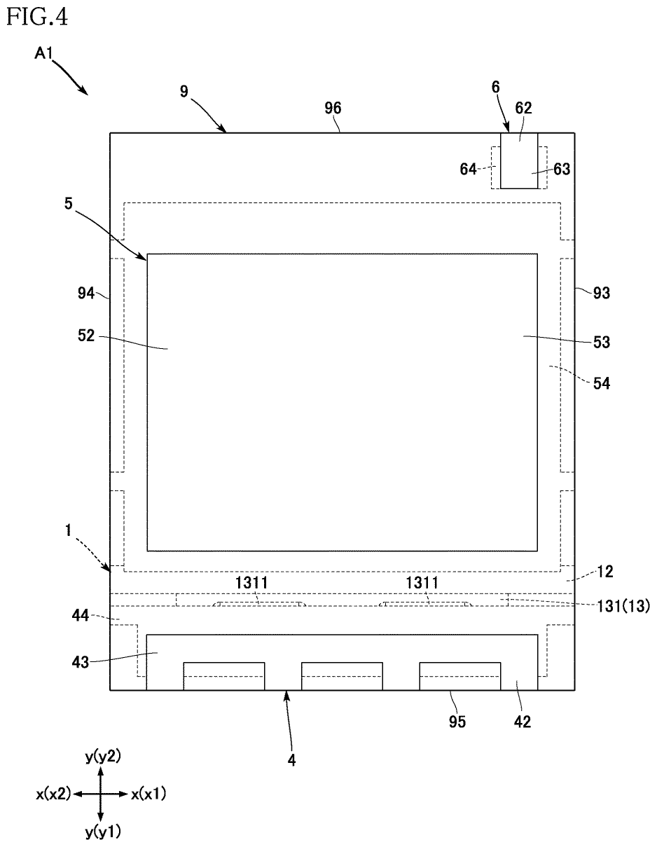

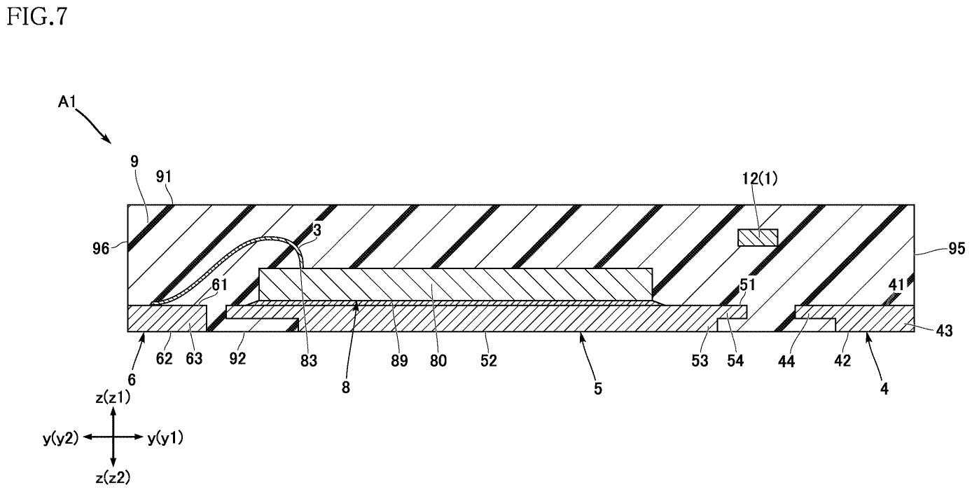

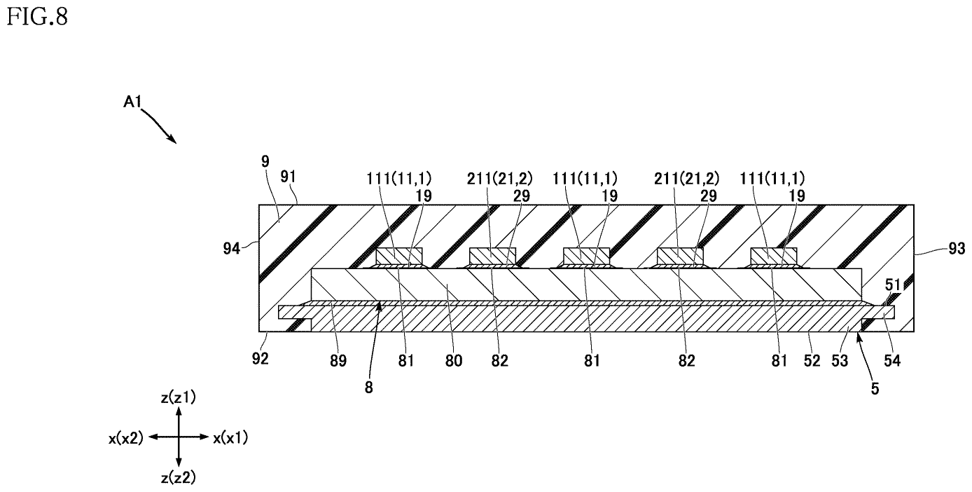

FIGS. 1 to 8 show a semiconductor device according to a first embodiment of the present disclosure. A semiconductor device A1 of the present embodiment includes a semiconductor element 8, a first lead 4, a second lead 5, a first conductive member 1, one or more second conductive members 2, and a sealing resin 9. The semiconductor device A1 may include a third lead 6 and a third conductive member 3. The specific functions and applications of the semiconductor device A1 are not particularly limited. The semiconductor device A1 may be used in a power conversion circuit such as a DC-DC converter or an inverter. The semiconductor device A1 may be provided in a quad flat non-leaded (QFN) package.

In these figures, an example of the “thickness direction” in the present disclosure ma be referred to as a first direction z. A first side in the first direction z may be referred to as a first side z1, and a second side opposite to the first side in the first direction z may be referred to as a second side z2. A direction perpendicular to the first direction z may be referred to as a second direction y. A first side in the second direction y may be referred to as a first side y1, and a second side opposite the first side y1 in the second direction y may be referred to as a second side y2. The direction perpendicular to the first direction z and the second direction y may be referred to as a third direction x. A first side in the third direction x may be referred to as a first side x1, and a second side opposite the first side x1 in the third direction x may be referred to as a second side x2.

### Semiconductor Element 8:

The semiconductor element 8 exerts the electrical functions of the semiconductor device A1. The specific configuration of the semiconductor element 8 is not particularly limited. In the present embodiment, the semiconductor element 8 is a switching element, which is a transistor using a nitride semiconductor, more specifically a high electron mobility transistor (GaN-HEMT) element using gallium nitride (GaN). The semiconductor element 8 is not limited to an element using a nitride semiconductor, and may be another semiconductor such as silicon (Si) or silicon carbide (SiC). The semiconductor element 8 is not limited to an HEMT, and may be another transistor such as a metal-oxide-semiconductor field-effect transistor (MOSFET) or an insulated gate bipolar transistor (IGBT). The semiconductor element 8 includes an element body 80, one or more first electrodes 81, one or more second electrodes 82, and a third electrode 83. The semiconductor element 8 is mounted on a second obverse surface 51 of the second lead 5.

The element body 80 may be a laminate including a substrate layer, a buffer layer, and a nitride layer (which are not illustrated). The element body 80 may be provided with a metal layer on the second side z2 in the first direction z. The metal layer and the second obverse surface 51 may be bonded via a bonding material 89. The bonding material 89 may be either electrically conductive or insulating. The conductive bonding material 89 may be solder, an Ag paste, an Ag sintered material, or a Cu sintered material. The semiconductor element 8 may be configured without the metal layer described above. Alternatively, the metal layer may have the same electrical potential as, for example, the second electrode 82. In the illustrated example, the semiconductor element 8 overlaps with a part of a second thick portion 53 and a part of a second thin portion 54 of the second lead 5 as viewed in the first direction z.

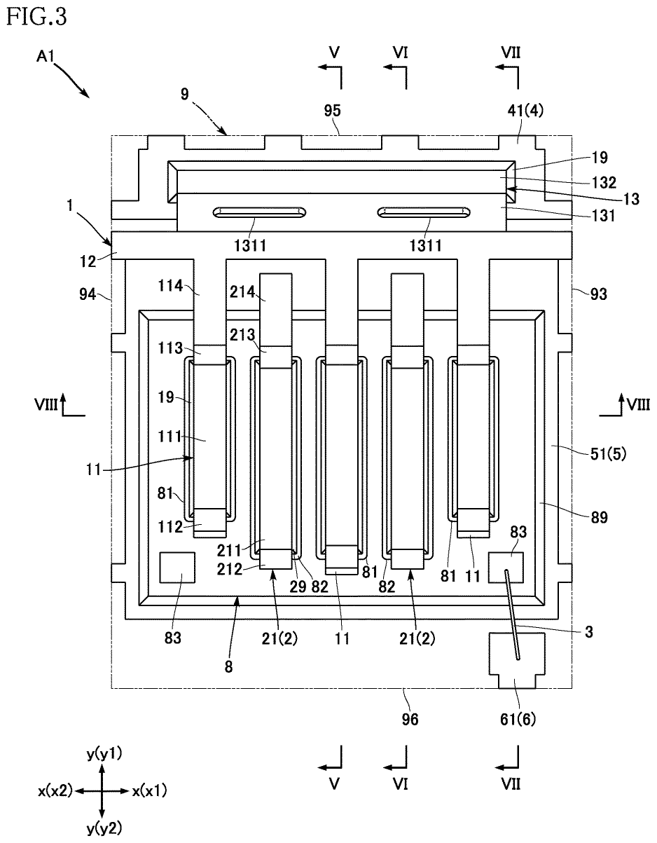

The one or more first electrodes 81, the one or more second electrodes 82, and the third electrode 83 are located on the element body 80 on the first side z1 in the first direction z. The respective numbers of first electrodes 81 and second electrodes 82 are not particularly limited. In the illustrated example, as shown in FIG. 3, three first electrodes 81 and two second electrodes 82 are provided. The number of first electrodes 81 may be the same as the number of first branch portions 11, and the number of second electrodes 82 may be the same as the number of second branch portions 21. In the present example, the first electrodes 81 may function as drain electrodes. The second electrodes 82 may function as source electrodes. Unlike the present example, the first electrodes 81 may function as source electrodes, and the second electrodes 82 may function as drain electrodes. The first electrodes 81 and the second electrodes 82 are alternately arranged in the third direction x.

The shapes of the first electrodes 81 and the second electrodes 82 are not particularly limited. In the illustrated example, each of the first electrodes 81 and the second electrodes 82 may have a shape elongated in the second direction y. The number of third electrodes 83 is not particularly limited. In the illustrated example, the semiconductor element 8 may include two third electrodes 83. The two third electrodes 83 may be spaced apart from each other in the third direction x.

### First Lead 4:

As shown in FIGS. 1 to 8, the first lead 4 has a first obverse surface 41 and a first terminal surface 42. The first lead 4 may include a first thick portion 43 and a first thin portion 44.

The first obverse surface 41 faces the first side z1 in the first direction z. In the illustrated example, the first obverse surface 41 may be a smooth surface perpendicular to the first direction z. The first lead 4 may include, as appropriate, a recess or a groove that is recessed from the first obverse surface 41. The first terminal surface 42 faces the second side z2 in the first direction z, and faces away from the first obverse surface 41. In the illustrated example, the first terminal surface 42 may be a smooth surface perpendicular to the first direction z. The first terminal surface 42 may be provided, as appropriate, with a plating layer made of nickel (Ni) or titanium (Ti).

The first thick portion 43 is a portion in which the first obverse surface 41 and the f terminal surface 42 overlap as viewed in the first direction z. In the illustrated example, the first thick portion 43 may be elongated in the third direction x as viewed in the first direction z. The shape of the first thick portion 43 is not particularly limited. The thickness of the first thick portion 43 in the first direction z is the distance between the first obverse surface 41 and the first terminal surface 42. The first thin portion 44 is a portion that overlaps with the first obverse surface 41 but does not overlap with the first terminal surface 42 as viewed in the first direction z. In the illustrated example, the first thin portion 44 extends from the first thick portion 43 in a direction intersecting the first direction z as viewed in the first direction z. The thickness of the first thin portion 44 in the first direction z is smaller than the distance between the first obverse surface 41 and the first terminal surface 42. The thicknesses of the first thick portion 43 and the first thin portion 44 are not particularly limited. By way of example, the thickness of the first thick portion 43 may be approximately 0.2 mm to 0.5 mm, and the thickness of the first thin portion 44 may be approximately 0.1 mm to 0.4 mm.

### Second Lead 5:

As shown in FIGS. 1 to 4, the second lead 5 is spaced apart from the first lead 4 tow the second side y2 in the second direction y. The center of the second lead 5 in the third direction x may be substantially the same in position as the center of the first lead 4 in the third direction x.

As shown in FIGS. 1 to 8, the second lead 5 has the second obverse surface 51 and a second terminal surface 52. The second lead 5 may include the second thick portion 53 and the second thin portion 54. The second obverse surface 51 faces the first side z1 in the first direction z. In the illustrated example, the second obverse surface 51 may be a smooth surface perpendicular to the first direction z. The second lead 5 may include, as appropriate, a recess or a groove that is recessed from the second obverse surface 51. The second terminal surface 52 faces the second side z2 in the first direction z, and faces away from the second obverse surface 51. In the illustrated example, the second terminal surface 52 may be a smooth surface perpendicular to the first direction z. The second terminal surface 52 may be provided, as appropriate, with a plating layer made of nickel (Ni) or titanium (Ti). In the present embodiment, the second obverse surface 51 may be located at substantially the same position as the first obverse surface 41 in the first direction z, and the second terminal surface 52 may be located at substantially the same position as the first terminal surface 42.

The semiconductor element 8 is bonded to the second obverse surface 51 via a bonding material 89. The bonding material 89 may be either electrically conductive or insulating.

The second thick portion 53 is a portion in which the second obverse surface 51 and second terminal surface 52 overlap as viewed in the first direction z. In the illustrated example, the second thick portion 53 may have a rectangular shape as viewed in the first direction z. The shape of the second thick portion 53 is not particularly limited. The thickness of the second thick portion 53 in the first direction z is the distance between the second obverse surface 51 and the second terminal surface 52. The second thin portion 54 is a portion that overlaps with the second obverse surface 51 but does not overlap with the second terminal surface 52 as viewed in the first direction z. In the illustrated example, the second thin portion 54 extends from the second thick portion 53 in a direction intersecting the first direction z, such as the third direction x or the second direction y, as viewed in the first direction z. The thickness of the second thin portion 54 in the first direction z is smaller than the distance between the second obverse surface 51 and the second terminal surface 52. The thicknesses of the second thick portion 53 and the second thin portion 54 are not particularly limited. In the present embodiment, the thickness of the second thick portion 53 may be substantially the same as the thickness of the first thick portion 43, and the thickness of the second thin portion 54 may be substantially the same as the thickness of the first thin portion 44. In the illustrated example, the second thin portion 54 may be configured such that a portion extending from the second thick portion 53 to the second side y2 in the second direction y is larger than a portion extending from the second thick portion 5 3 to the first side y1 in the second direction y.

### Third Lead 6:

As shown in FIGS. 1 to 4 and 7, the third lead 6 may be located on the second side y2 in the second direction y relative to the second lead 5. The center of the third lead 6 in the third direction x may be offset from the center of the second lead 5 in the third direction x to the first side x1 in the third direction x. The third lead 6 has a third obverse surface 61 and a third terminal surface 62. The third lead 6 may include a third thick portion 63 and a third thin portion 64.

The third obverse surface 61 faces the first side z1 in the first direction z. In the illustrated example, the third obverse surface 61 may be a smooth surface perpendicular to the first direction z. The third lead 6 may include, as appropriate, a recess or a groove that is recessed from the third obverse surface 61. The third terminal surface 62 faces the second side z2 in the first direction z and faces away from the third obverse surface 61. In the illustrated example, the third terminal surface 62 may be a smooth surface perpendicular to the first direction z. The third terminal surface 62 may be provided, as appropriate, with a plating layer made of nickel (Ni) or titanium (Ti). In the present embodiment, the third obverse surface 61 may be located at substantially the same position as the first obverse surface 41 and the second obverse surface 51 in the first direction z, and the third terminal surface 62 may be located at substantially the same position as the first terminal surface 42 and the second terminal surface 52.

The third thick portion 63 is a portion in which the third obverse surface 61 and the terminal surface 62 overlap as viewed in the first direction z. In the illustrated example, the third thick portion 63 may have a rectangular shape as viewed in the first direction z. The shape of the third thick portion 63 is not particularly limited. The thickness of the third thick portion 63 in the first direction z is the distance between the third obverse surface 61 and the third terminal surface 62. In the present embodiment, the third thin portion 64 is a portion that overlaps with the third obverse surface 61 but does not overlap with the third terminal surface 62 as viewed in the first direction z. In the illustrated example, the third thin portion 64 extends from the third thick portion 63 in a direction intersecting with the first direction z as viewed in the first direction z. The thickness of the third thin portion 64 in the first direction z is smaller than the distance between the third obverse surface 61 and the third terminal surface 62. The thicknesses of the third thick portion 63 and the third thin portion 64 are not particularly limited. In the present embodiment, the thickness of the third thick portion 63 may be substantially the same as the thickness of each of the first thick portion 43 and the second thick portion 53, and the thickness of the third thin portion 64 may be substantially the same as the thickness of each of the first thin portion 44 and the second thin portion 54.

### First Conductive Member 1:

As shown in FIGS. 1 to 3 and FIGS. 5 to 8, the first conductive member 1 is offset from the first lead 4, the second lead 5, and the third lead 6 to the first side z1 in the first direction z. The first conductive member 1 in the present embodiment includes a first main portion 12, one or more first branch portions 11, and a first connecting portion 13.

In the illustrated example, the first main portion 12 may have a shape elongated in th third direction x. The one or more first branch portions 11 and the first connecting portion 13 are connected to the first main portion 12.

The one or more first branch portions 11 may extend along the second direction y from the first main portion 12 to the second side y2 in the second direction y. The number of first branch portions 11 is not limited. In the illustrated example, three first branch portions 11 may be provided. The first branch portions 11 may be aligned in the third direction x. Each of the first branch portions 11 may include a first bonding portion 111. Each of the first branch portions 11 may include a first front end portion 112, a first rear end portion 113, and a first root portion 114.

The first bonding portion 111 is located on the second side y2 in the second direction y relative to the first main portion 12. The first bonding portion 111 may be located on the second side z2 in the first direction z relative to the first main portion 12. The shape of the first bonding portion 111 is not particularly limited. In the illustrated example, the first bonding portion 111 may have a shape elongated in the second direction y, as viewed in the first direction z. The first bonding portion 111 may be perpendicular to the first direction z.

The first bonding portion 111 is electrically bonded to one of the first electrodes 81 via a conductive bonding material 19. The conductive bonding material 19 may be solder, an Ag paste, an Ag sintered material, or a Cu sintered material.

The first root portion 114 is located between the first bonding portion 111 and the first main portion 12, and may be connected to the first main portion 12. The shape of the first root portion 114 is not particularly limited. In the illustrated example, the first root portion 114 may have a band shape extending along the second direction y.

The first front end portion 112 is connected to the first bonding portion 111 on the second side y2 in the second direction y. The first front end portion 112 is spaced apart from the first electrode 81. The first front end portion 112 may be inclined toward the first side z1 in the first direction z as proceeding toward the second side y2 in the second direction y.

The first rear end portion 113 is located between the first bonding portion 111 and the first root portion 114. The first rear end portion 113 is spaced apart from the first electrode 81. The first rear end portion 113 may be inclined toward the first side z1 in the first direction z as proceeding toward the first side y1 in the second direction y.

In the illustrated example, the three first branch portions 11 may include first branch portions 11 having different lengths in the second direction y. The first branch portion 11 at the center in the third direction x may be longer in the second direction y than the other first branch portions 11. The first branch portions 11 may all have equal lengths.

The first connecting portion 13 is connected to the end of the first main portion 12 located on the first side y1 in the second direction y, opposite to the first branch portion 11. The first connecting portion 13 extends from the first main portion 12 to the second side z2 in the first direction z. The shape of the first connecting portion 13 is not particularly limited. In the illustrated example, the first connecting portion 13 may have a shape elongated in the third direction x. In the illustrated example, the center of the first connecting portion 13 in the third direction x may be the same (or substantially the same) as the center of the first main portion 12 in the third direction x.

The first connecting portion 13 may include an inclined portion 131 and a bonding portion 132. The inclined portion 131 is connected to the first main portion 12. The inclined portion 131 is inclined toward the second side z2 in the first direction z as proceeding toward the first side y1 in the second direction y. The inclined portion 131 may include a through-hole 1311. The bonding portion 132 is connected to the end of the inclined portion 131 on the second side z2 in the first direction z. The bonding portion 132 is electrically bonded to the first obverse surface 41 of the first lead 4 via the conductive bonding material 19.

### Second Conductive Member 2:

As shown in FIGS. 1 to 3, 6 and 8, the one or more second conductive members 2 offset to the first side z1 in the first direction z from the first lead 4, the second lead 5, and the third lead 6. The number of second conductive members 2 is not particularly limited. The illustrated semiconductor device A1 may include two second conductive members 2. The two second conductive members 2 are aligned in the third direction x. Each of the second conductive members 2 is located between two adjacent first branch portions 11 in the third direction x.

Each of the second conductive members 2 in the present embodiment may include a second branch portion 21 and a second connecting portion 23.

The second branch portion 21 extends in the second direction y. The second branch portion 21 may include a second front end portion 212, a second rear end portion 213, and a second root portion 214.

A second bonding portion 211 may be located on the second side z2 in the first direction z relative to the first main portion 12. The shape of the second bonding portion 211 is not particularly limited. In the illustrated example, the second bonding portion 211 may have a shape elongated in the second direction y, as viewed in the first direction z. The second bonding portion 211 may be perpendicular to the first direction z. The second bonding portion 211 may overlap with the first bonding portion 111 as viewed in the third direction x. In other words, the second branch portion 21 may overlap with the first branch portion 11 as viewed in the third direction x. In the illustrated example, the positions of the first bonding portion 111 and the second bonding portion 211 in the first direction z may be the same (or substantially the same).

The second bonding portion 211 is electrically bonded to one of the second electrodes 82 via a conductive bonding material 29. The conductive bonding material 29 may be solder, an Ag paste, an Ag sintered material, or a Cu sintered material.

The second root portion 214 is located on the first side y1 in the second direction y relative to the second bonding portion 211. The shape of the second root portion 214 is not particularly limited. In the illustrated example, the second root portion 214 may have a band shape extending along the second direction y. The second root portion 214 may be located on the first side z1 in the first direction z relative to the second bonding portion 211.

The second front end portion 212 is connected to the second bonding portion 211 on second side y2 in the second direction y. The second front end portion 212 is spaced apart from the second electrode 82. The second front end portion 212 may be inclined toward the first side z1 in the first direction z as proceeding toward the second side y2 in the second direction y.

The second rear end portion 213 is located between the second bonding portion 211 and the second root portion 214. The second rear end portion 213 is spaced apart from the second electrode 82. The second rear end portion 213 may be inclined toward the first side z1 in the first direction z as proceeding toward the first side y1 in the second direction y.

In the illustrated example, the two second conductive members 2 may have the same length in the second direction y. The two second conductive members 2 may have different lengths in the second direction y.

The second connecting portion 23 is connected to the second root portion 214 on the first side y1 in the second direction y. The second connecting portion 23 extends from the second root portion 214 to the second side z2 in the first direction z. The shape of the second connecting portion 23 is not particularly limited. In the illustrated example, the second connecting portion 23 may have a shape standing upright in the first direction z.

The end of the second connecting portion 23 on the second side z2 in the first direction z is electrically bonded to the second obverse surface 51 of the second lead 5 via the conductive bonding material 29. In the illustrated example, the end of the second connecting portion 23 on the second side z2 in the first direction z is electrically bonded to the portion of the second obverse surface 51 that extends from the semiconductor element 8 to the first side y1 in the second direction y.

### Third Conductive Member 3:

The third conductive member 3 electrically connects the third electrode 83 and the third lead 6. One end of the third conductive member 3 is bonded to the third electrode 83. The other end of the third conductive member 3 is bonded to the third obverse surface 61. The specific configuration of the third conductive member 3 is not particularly limited. In the illustrated example, the third conductive member 3 may be a wire. The third conductive member 3 may contain a metal such as gold (Au), copper (Cu), or an alloy thereof.

In the semiconductor device A1, the first lead 4 is electrically connected to the one or more first electrodes 81 of the semiconductor element 8 via the first conductive member 1. The second lead 5 is electrically connected to the one or more second electrodes 82 of the semiconductor element 8 via the one or more second conductive members 2. The third lead 6 is electrically connected to the third electrode 83 of the semiconductor element 8 via the third conductive member 3.

### Sealing Resin 9:

The sealing resin 9 covers the first conductive member 1 and the second conductive members 2, as well as parts of the first lead 4 and the second lead 5. The sealing resin 9 exposes the first terminal surface 42 and the second terminal surface 52. The sealing resin 9 may cover a part of the third lead 6 and the third conductive member 3. The sealing resin 9 is made of an insulating material such as epoxy resin. As shown in FIGS. 3 to 8, the sealing resin 9 may include a resin first surface 91, a resin second surface 92, a resin third surface 93, a resin fourth surface 94, a resin fifth surface 95, and a resin sixth surface 96, and may have a rectangular parallelepiped shape.

The resin first surface 91 faces the first side z1 in the first direction z. In the illustrated example, the resin first surface 91 may be a flat surface perpendicular to the first direction z. The resin second surface 92 faces the second side z2 in the first direction z. In the illustrated example, the resin second surface 92 may be a flat surface perpendicular to the first direction z.

The resin third surface 93 faces the first side x1 in the third direction x. In the illustrated example, the resin third surface 93 may be a flat surface perpendicular to the third direction x. The resin fourth surface 94 faces the second side x2 in the third direction x. In the illustrated example, the resin fourth surface 94 may be a flat surface perpendicular to the third direction x.

The resin fifth surface 95 faces the first side y1 in the second direction y. In the illustrated example, the resin fifth surface 95 may be a flat surface perpendicular to the second direction y. The resin sixth surface 96 faces the second side y2 in the second direction y. In the illustrated example, the resin sixth surface 96 may be a flat surface perpendicular to the second direction y.

The first terminal surface 42 and the second terminal surface 52 are exposed from the resin second surface 92. The third terminal surface 62 may be exposed from the resin second surface 92. One or more of the first terminal surface 42, the second terminal surface 52, and the third terminal surface 62 may be flush with the resin second surface 92. One or more of the first terminal surface 42, the second terminal surface 52, and the third terminal surface 62 may protrude slightly from the resin second surface 92.

The first main portion 12, the first thin portion 44, and the second thin portion 54 may exposed from the resin third surface 93. The first main portion 12, the first thin portion 44, and the second thin portion 54 may be exposed from the resin fourth surface 94. The first thin portion 44 may be exposed from the resin fifth surface 95. The third thin portion 64 may be exposed from the resin sixth surface 96.

The semiconductor device A1 may be mounted on a circuit board (not illustrated) or like, with the first terminal surface 42, the second terminal surface 52, and the third terminal surface 62, which are exposed from the resin second surface 92, serving as mounting terminals. In the semiconductor device A1, the surfaces located on the second side z2 in the first direction z may serve as mounting surfaces. The second terminal surface 52 may function as a heat dissipation surface for dissipating heat from the semiconductor element 8.

Next, advantages of the semiconductor device A1 will be described.

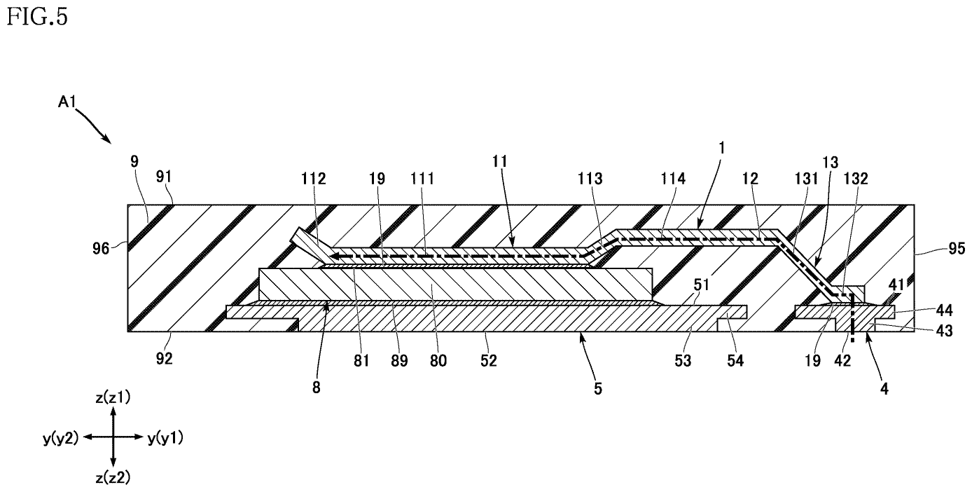

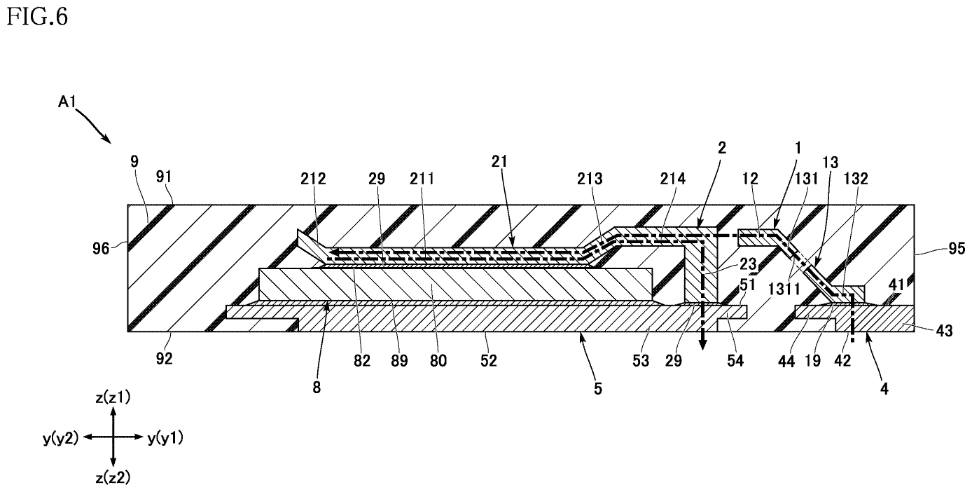

When the first electrodes 81 are drain electrodes and the second electrodes 82 are source electrodes, and the semiconductor element 8 is switched on as shown in FIG. 5, the current entering from the first terminal surface 42 flows to the first electrodes 81 along the first conductive member 1 as indicated by a dash-dot arrow in the figure. This current flows from the second electrodes 82 to the second bonding portions 211 via the element body 80, as shown in FIG. 6. Next, the current flowing along the second conductive members 2 flows to the second lead 5. As can be understood from FIG. 6, the area of the current loop formed by the first branch portions 11 and the second branch portions 21 is quite small as viewed in the third direction x. For example, unlike the present embodiment, in a configuration in which the current from the second electrodes 82 flows to the second side y2 in the second direction y relative to the semiconductor element 8 via the second conductive members 2 and then flows to the second side z2 in the first direction z, a current loop including the semiconductor element 8 may be formed as viewed in the third direction x. As compared to such a configuration, the semiconductor device A1 can reduce the area of the current loop. This makes it possible to reduce inductance. In particular, when the switching frequency of the semiconductor element 8 is a high frequency of approximately several MHz, reducing inductance can improve operational efficiency.

Since the first conductive member 1 includes the first branch portions 11 and the first main portion 12, a mounting process for the first conductive member 1 can be performed more easily.

Since the first branch portions 11 and the second branch portions 21 overlap with each other as viewed in the third direction x, the area of the current loop can be further reduced.

Since the second connecting portions 23 are connected to the portions of the second obverse surface 51 that are offset from the semiconductor element 8 to the first side y1 of the second direction y, the area of the current loop can be further reduced.

Since the first connecting portion 13 includes the inclined portion 131, the area of the current loop can be further reduced.

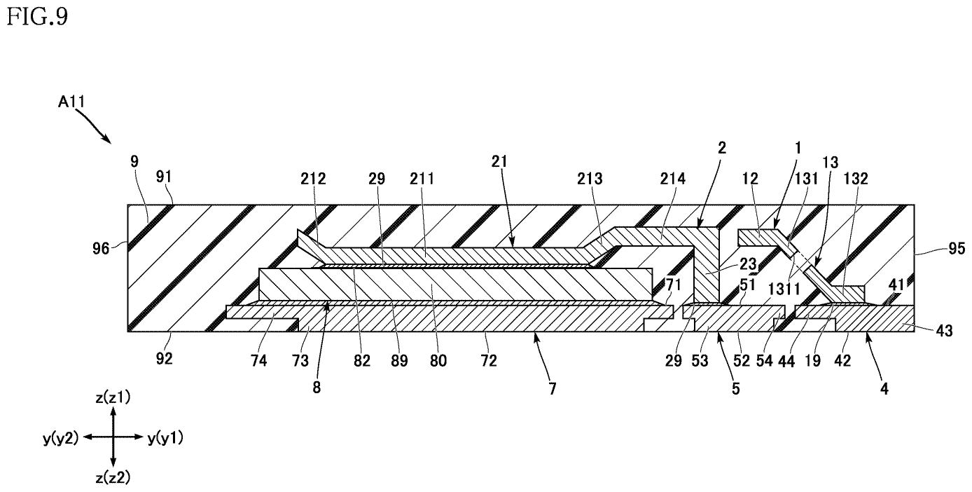

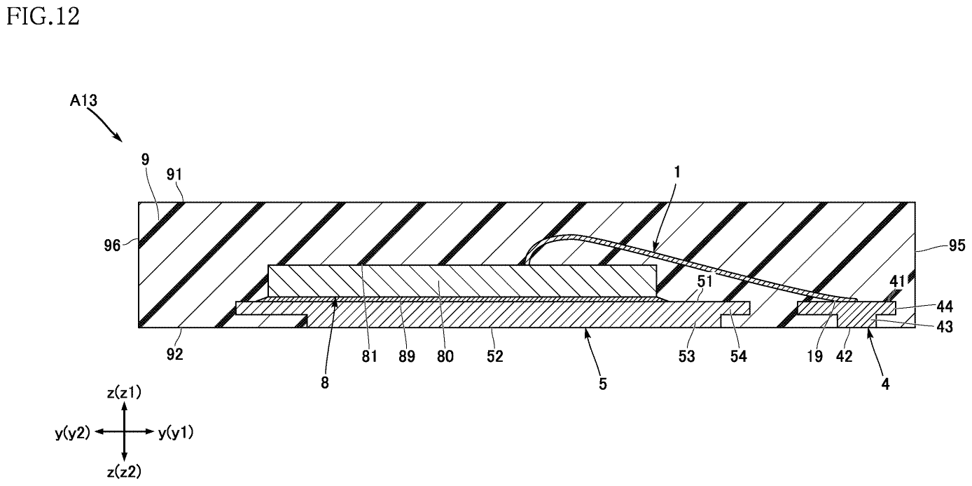

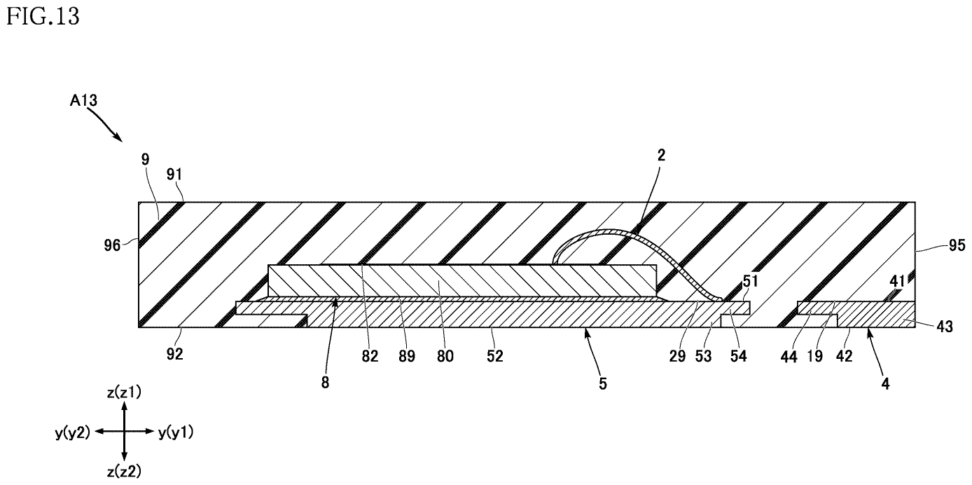

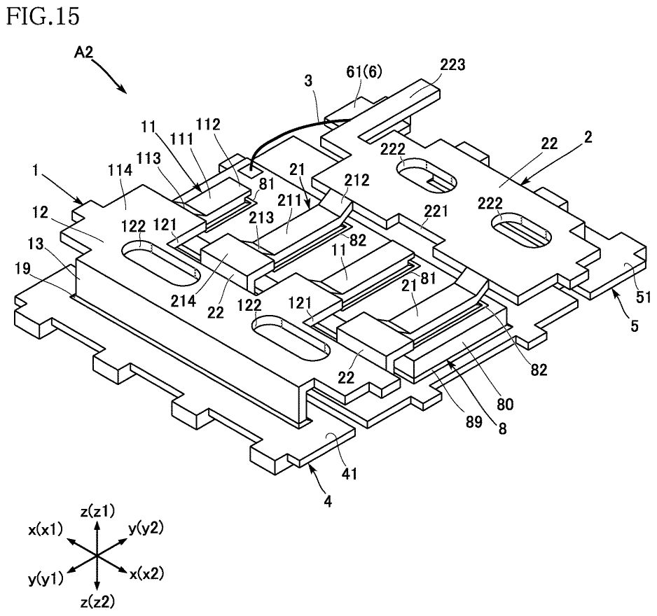

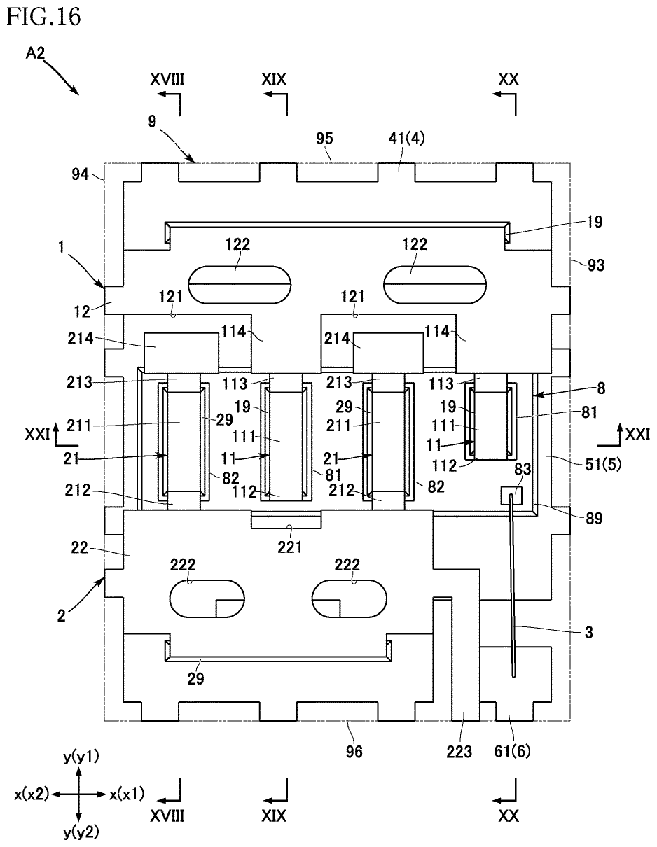

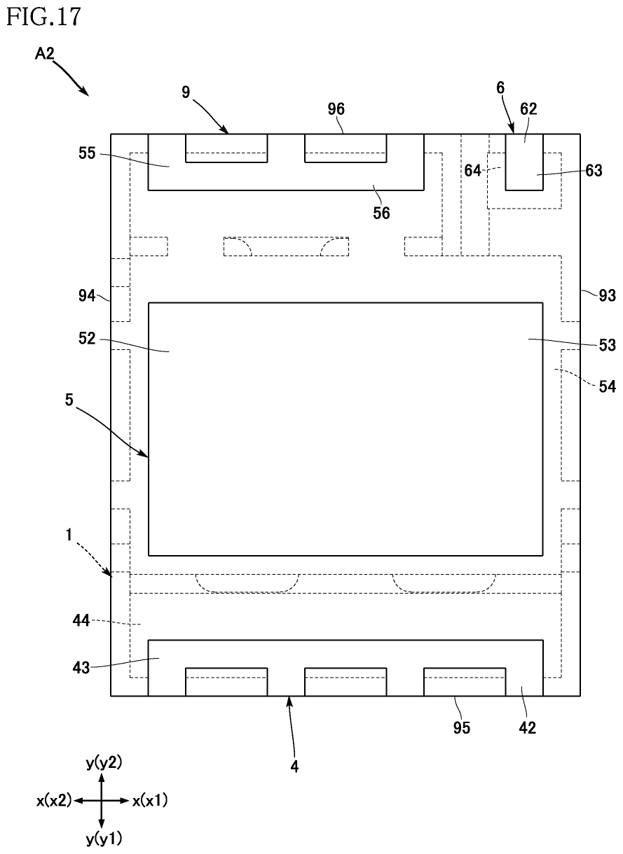

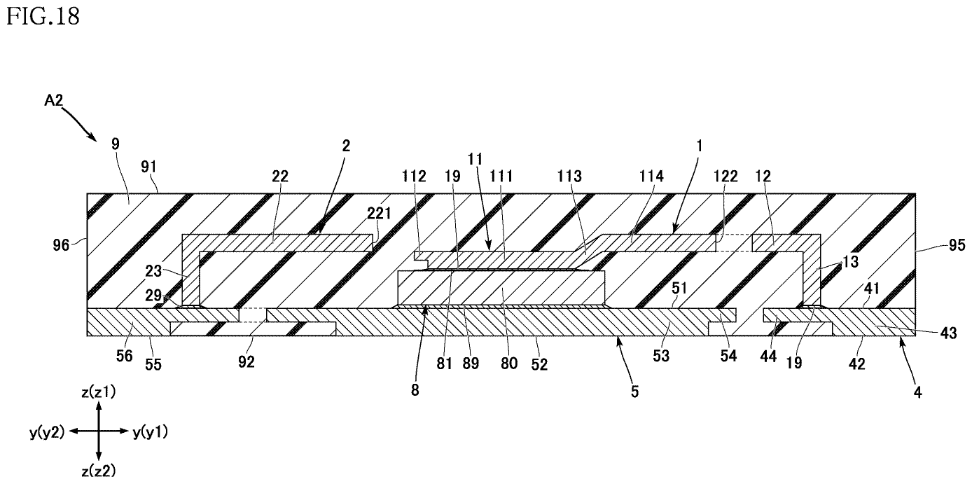

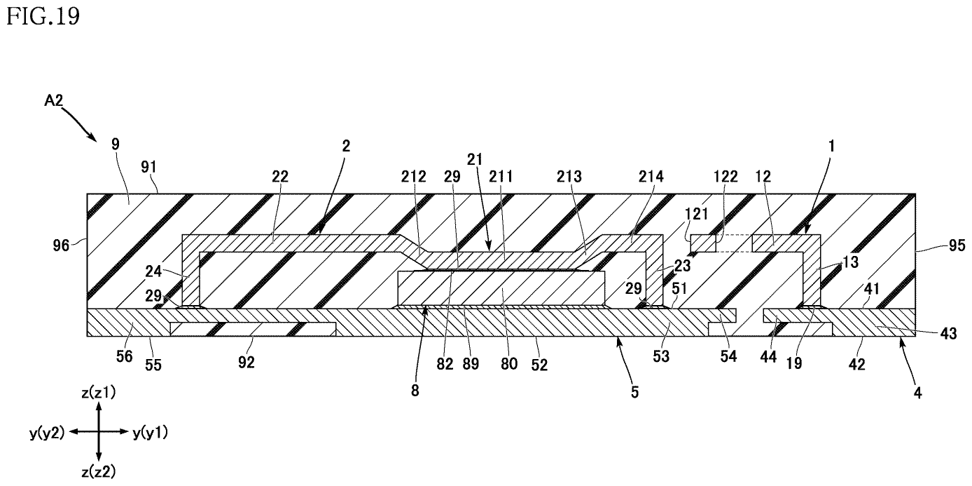

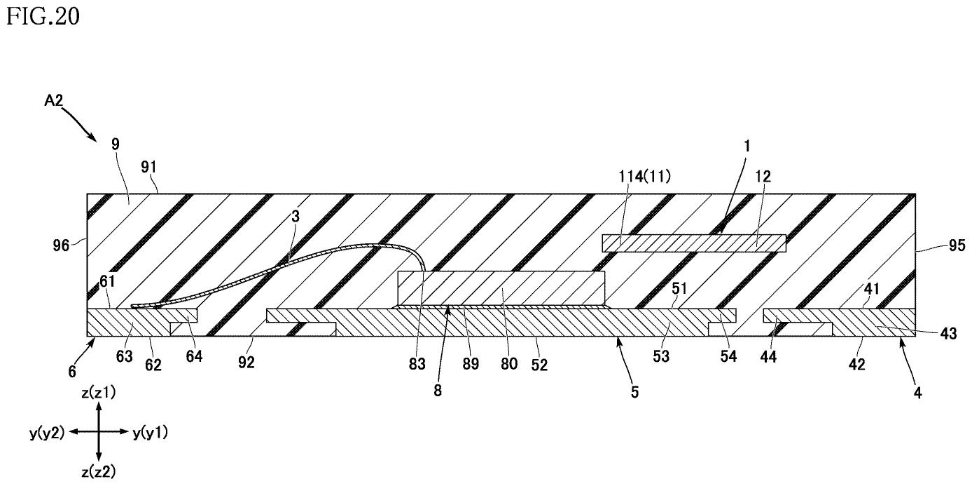

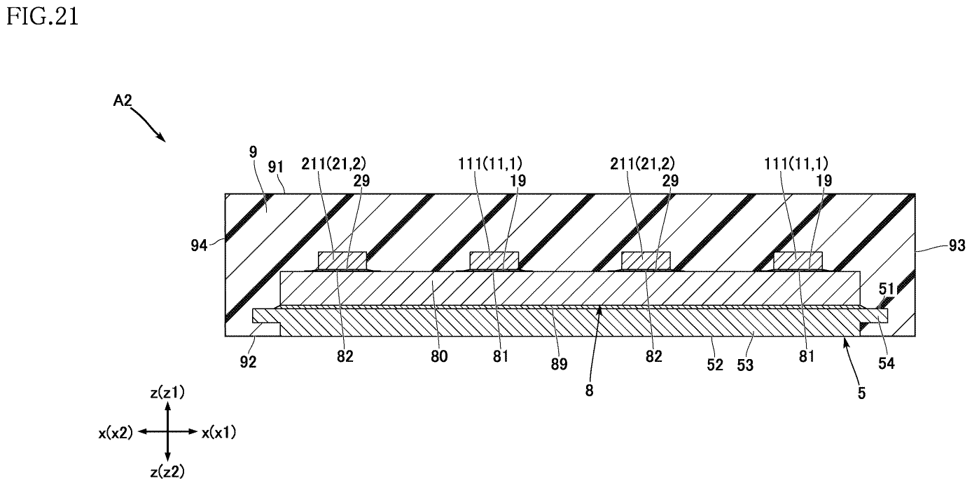

FIGS. 9 to 22 show other embodiments of the present disclosure. In these figures, elements that are the same as or similar to the elements in the above embodiment are provided with the same reference numerals as in the above embodiment. The configurations of the elements in each variation and each embodiment can be combined as appropriate as long as the combination does not cause technical inconsistency.

### First Variation of the First Embodiment

FIG. 9 shows a first variation of the semiconductor device A1. A semiconductor device A11 of the present variation further includes a fourth lead 7.

The fourth lead 7 is located on the second side y2 in the second direction y relative the second lead 5. The fourth lead 7 is spaced apart from the second lead 5. The fourth lead 7 has a fourth obverse surface 71 and a fourth terminal surface 72. The fourth obverse surface 71 faces the first side z1 in the first direction z. The semiconductor element 8 is bonded to the fourth obverse surface 71 via the bonding material 89. The fourth terminal surface 72 faces the second side z2 in the first direction z. The fourth terminal surface 72 is exposed from the resin second surface 92.

The fourth lead 7 may include a fourth thick portion 73 and a fourth thin portion 74. The fourth thick portion 73 is a portion in which the fourth obverse surface 71 and the fourth terminal surface 72 overlap as viewed in the first direction z. In the illustrated example, the fourth thick portion 73 may have a rectangular shape as viewed in the first direction z. The shape of the fourth thick portion 73 is not particularly limited. The thickness of the fourth thick portion 73 in the first direction z is the distance between the fourth obverse surface 71 and the fourth terminal surface 72. The fourth thin portion 74 is a portion that overlaps with the fourth obverse surface 71 but does not overlap with the fourth terminal surface 72 as viewed in the first direction z. In the illustrated example, the fourth thin portion 74 extends from the fourth thick portion 73 in a direction intersecting the first direction z, such as the third direction x or the second direction y, as viewed in the first direction z. The thickness of the fourth thin portion 74 in the first direction z is smaller than the distance between the fourth obverse surface 71 and the fourth terminal surface 72. The thicknesses of the fourth thick portion 73 and the fourth thin portion 74 are not particularly limited. In the present embodiment, the thickness of the fourth thick portion 73 may be substantially the same as the thickness of the second thick portion 53, and the thickness of the fourth thin portion 74 may be substantially the same as the thickness of the second thin portion 54.

The present variation can reduce inductance. As can be understood from the present variation, it is possible to employ either a configuration in which the semiconductor element 8 is mounted on the second lead 5 or a configuration in which the semiconductor element 8 is mounted on the fourth lead 7 instead of the second lead 5.

### Second Variation of the First Embodiment

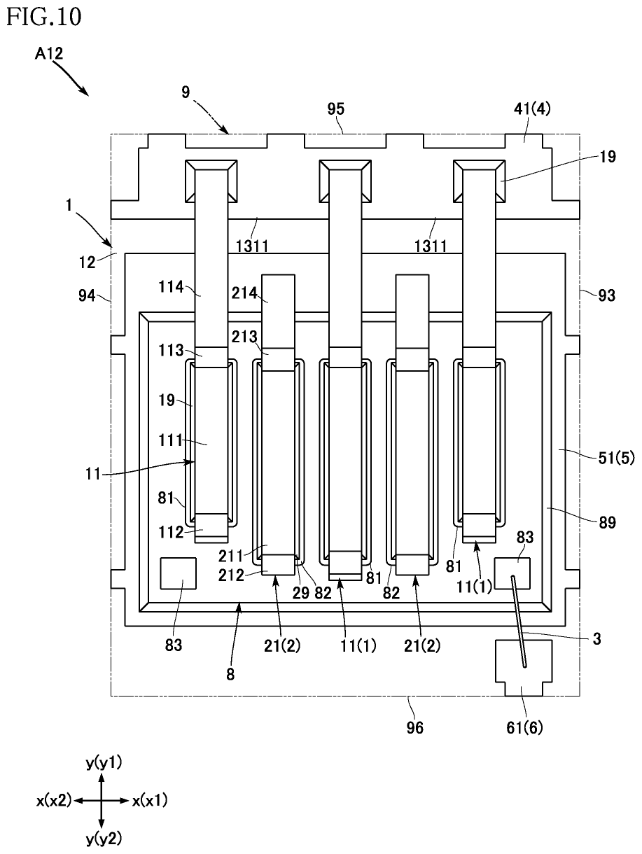

FIG. 10 shows a second variation of the semiconductor device A1. A semiconductor device A12 of the present variation includes a plurality of first conductive members 1.

The number of first conductive members 1 corresponds to the number of first electrodes 81. In the illustrated example, three first conductive members 1 are provided. Each of the first conductive members 1 may include a first branch portion 11 and a first connecting portion 13.

The present variation can reduce inductance. As can be understood from the present variation, it is possible to employ either a configuration in which one first conductive member 1 includes a plurality of first branch portions 11 or a configuration in which a plurality of first conductive members 1 each include a single first branch portion 11.

### Third Variation Of The First Embodiment

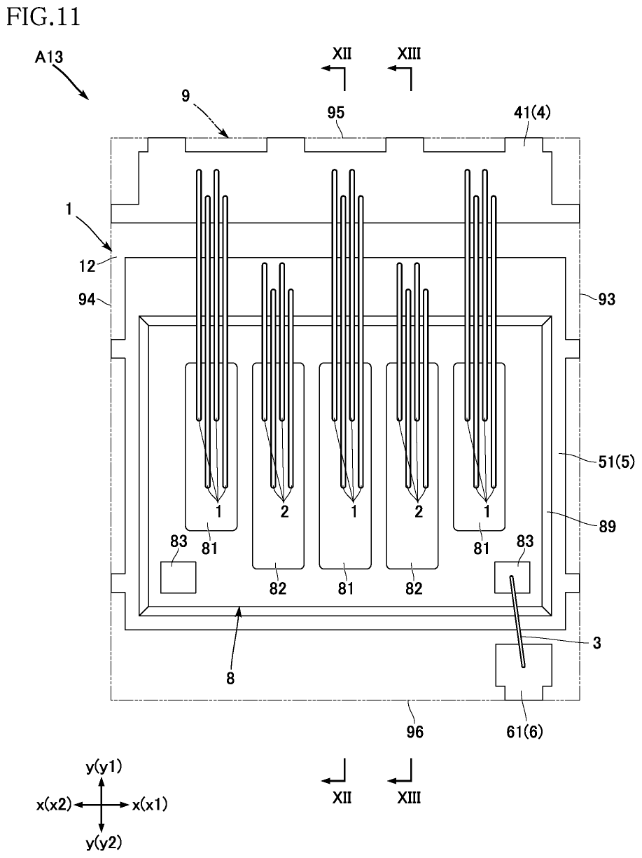

FIGS. 11 to 13 show a third variation of the semiconductor device A1. In the semiconductor device A13 of the present variation, each of the first conductive members 1 is made of one or more wires. Each of the second conductive members 2 is made of one or more wires.

The number of wires constituting the first conductive member 1 is not particularly limited and may be one or more. The wires may contain a metal such as copper (Cu), aluminum (Al), gold (Au), or an alloy thereof.

The number of wires constituting the second conductive member 2 is not particularly limited, and may be one or more. The wires may contain a metal such as copper (Cu), aluminum (Al), gold (Au), or an alloy thereof.

The present variation can reduce inductance. As can be understood from the present variation, the first conductive members 1 and the second conductive members 2 may be configured in various forms, such as a metal plate or a wire.

### Second Embodiment

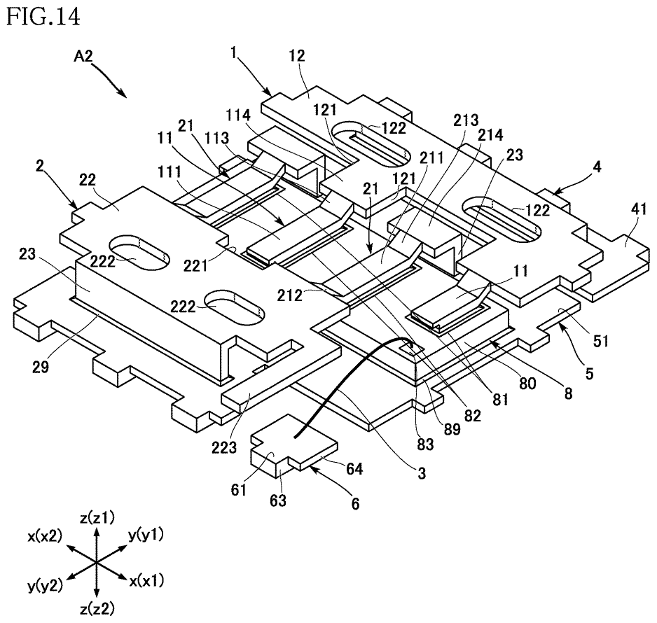

FIGS. 14 to 21 show a semiconductor device according to a second embodiment of the present disclosure. A semiconductor device A2 of the present embodiment is different from the above embodiment mainly in the configuration relating to the second conductive member 2.

In the present embodiment, the second conductive member 2 includes a second main portion 22 and a third connecting portion 24, in addition to the one or more second branch portions 21 and the second connecting portion 23.

The number of second branch portions 21 is not particularly limited. In the illustrated example, the second conductive member 2 may include two second branch portions 21.

The second main portion 22 is located on the second side y2 in the second direction y relative to the two second branch portions 21. The second main portion 22 may be connected to the second front end portions 212 of the two second branch portions 21. The second main portion 22 may be located on the first side z1 in the first direction z relative to the two second branch portions 21. The second main portion 22 may include a second through-hole 222. The second through-hole 222 penetrates the second main portion 22 in the first direction z.

The third connecting portion 24 is connected to the second main portion 22 on the second side y2 in the second direction y. The third connecting portion 24 extends from the second main portion 22 to the second side z2 in the first direction z. The end of the third connecting portion 24 on the second side z2 in the first direction z is electrically bonded to the second obverse surface 51 via the conductive bonding material 29.

The second main portion 22 may include an extending portion 223. The extending portion 223 may include a first portion extending from the second main portion 22 to the first side x1 in the third direction x, and a second portion extending from the first portion to the second side y2 in the second direction y.

The second main portion 22 may include a second recess 221. The second recess 221 is recessed toward the second side y2 in the second direction y. As viewed in the first direction z, the second recess 221 faces the tip of a first branch portion 11 that is located on the second side y2 in the second direction y.

The first main portion 12 may include one or more first recesses 121. Each of the first recesses 121 is recessed toward the first side y1 in the second direction y. As viewed in the first direction z, each of the first recesses 121 faces a second root portion 214.

The first main portion 12 may include a first through-hole 122. The first through-hole 122 penetrates the first main portion 12 in the first direction z.

The second lead 5 may include a fifth terminal surface 55 and an additional thick portion 56. The fifth terminal surface 55 faces the second side z2 in the first direction z. The fifth terminal surface 55 may be exposed from the resin second surface 92. The fifth terminal surface 55 is located on the second side y2 in the second direction y relative to the second terminal surface 52. The additional thick portion 56 is a portion which overlaps the second obverse surface 51 and the fifth terminal surface 55 as viewed in the first direction z.

In the semiconductor device A2, the first electrodes 81 may be drain electrodes, and the second electrodes 82 may be source electrodes.

The semiconductor device A2 can reduce inductance. The fifth terminal surface 55 is electrically connected to the second electrodes 82 of the semiconductor element 8 via the second branch portions 21, the second main portion 22, and the third connecting portion 24. The fifth terminal surface 55 may be used as a source sense terminal of the semiconductor device A2.

### First Variation of the Second Embodiment

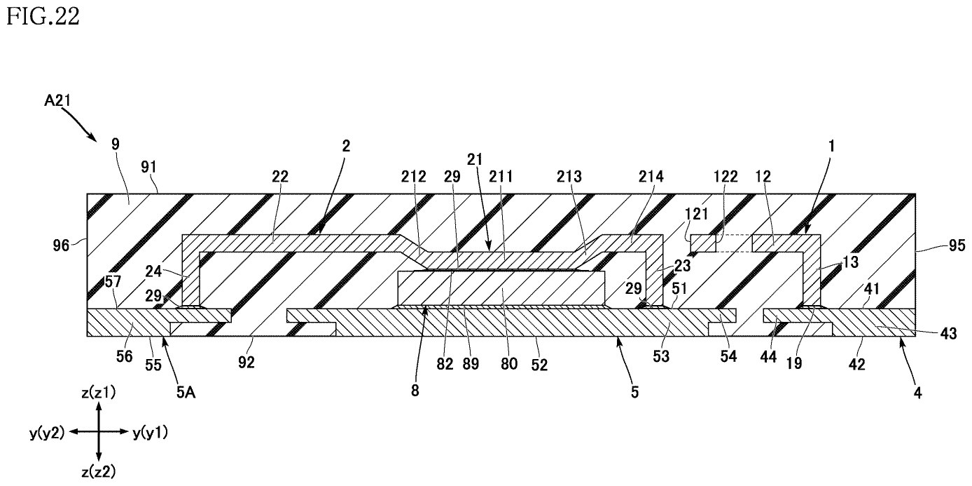

FIG. 22 shows a first variation of the semiconductor device A2. A semiconductor device A21 of the present variation further includes a fifth lead 5A.

The fifth lead 5A is located on the second side y2 in the second direction y relative the second lead 5. The fifth lead 5A has a fifth obverse surface 57. The fifth obverse surface 57 faces the first side z1 in the first direction z. The fifth lead 5A has the fifth terminal surface 55 described above. The additional thick portion 56 of the fifth lead 5A is a portion which overlaps the fifth obverse surface 57 and the fifth terminal surface 55 as viewed in the first direction z.

The present variation can reduce inductance. As can be understood from the present variation, the second terminal surface 52 and the fifth terminal surface 55 may be formed by parts of the same lead or by different leads.

The semiconductor device according to the present disclosure is not limited to the above embodiments. Various design changes can be made to the specific configurations of the elements of the semiconductor device according to the present disclosure. The present disclosure includes the embodiments described in the following clauses.

### Clause 1.

A semiconductor device (A1) comprising:
a semiconductor element (8) including an element body (80), a first electrode (81) located on a first side (z1) in a first direction (z) relative to the element body (80), and a second electrode (82) located on the first side (z1) in the first direction (z) relative to the element body (80);
a first lead (4) located on a first side (y1) in a second direction (y) intersecting the first direction (z) relative to the semiconductor element (8), the first lead (4) including a first terminal surface (42);
a second lead (5) including a second terminal surface (52) located on a second side (y2) in the second direction (y) relative to the first lead (4);
a first conductive member (1) extending from the semiconductor element (8) to the first side (y1) in the second direction (y), and electrically connecting the first electrode (81) and the first lead (4);
a second conductive member (2) extending from the semiconductor element (8) to the first side (y1) in the second direction (y), and electrically connecting the second electrode (82) and the second lead (5); and
a sealing resin (9) covering the semiconductor element (8), the first conductive member (1), the second conductive member (2), and parts of the first lead (4) and the second lead (5), while exposing the first terminal surface (42) and the second terminal surface (52).

### Clause 2.

The semiconductor device (A1) according to clause 1, wherein the semiconductor element (8) includes a plurality of the first electrodes (81) and a plurality of the second electrodes (82), and
the plurality of first electrodes (81) and the plurality of second electrodes (82) are alternately arranged in a third direction (x) intersecting the first direction (z) and the second direction (y).

### Clause 3.

The semiconductor device (A1) according to clause 2, wherein the first conductive member (1) includes a plurality of first branch portions (11) and a first connecting portion (13),
each of the plurality of first branch portions (11) has a shape extending along the second direction (y), and is electrically bonded to one of the plurality of first electrodes (81), and
the first connecting portion (13) is located on the first side (y1) in the second direction (y) relative to the plurality of first branch portions (11), and is electrically bonded to the first lead (4).

### Clause 4.

The semiconductor device (A1) according to clause 3, comprising a plurality of the second conductive members (2) corresponding to the plurality of second electrodes (82), respectively,
wherein each of the plurality of second conductive members (2) includes a second branch portion (21) and a second connecting portion (23),
the second branch portion (21) has a shape extending along the second direction (y), a is electrically bonded to one of the plurality of second electrodes (82), and
the second connecting portion (23) is located on the first side (y1) in the second direction (y) relative to the second branch portion (21), and is electrically bonded to the second lead (5).

### Clause 5.

The semiconductor device (A1) according to clause 4, wherein the plurality of first branch portions (11) and the second branch portions (21) of the plurality of second conductive members (2) overlap as viewed in the third direction (x).

### Clause 6.

The semiconductor device (A1) according to any one of clauses 3 to 5, wherein the first connecting portion (13) includes an inclined portion (131) inclined relative to the first direction (z) and the second direction (y).

### Clause 7.

The semiconductor device (A1) according to clause 6, wherein the inclined portion (131) includes a through-hole (1311).

### Clause 8.

The semiconductor device (A1) according to any one of clauses 3 to 7, wherein the first conductive member (1) includes a first main portion (12) interposed between the plurality of first branch portions (11) and the first connecting portion (13), and extending in the third direction (x).

### Clause 9.

The semiconductor device (A1) according to clause 8, wherein the first main portion (12) located on the first side (z1) in the first direction (z) relative to the plurality of first branch portions (11).

### Clause 10.

The semiconductor device (A1) according to any one of clauses 1 to 9, wherein the second conductive member (2) is connected to a portion of the second lead (5) that is located on the first side (y1) in the second direction (y) relative to the semiconductor element (8).

### Clause 11.

The semiconductor device (A1) according to any one of clauses 1 to 10, wherein the sealing resin (9) includes a resin first surface (91) facing the first side (z1) in the first direction (z), and a resin second surface (92) facing a second side (z2) in the first direction (z), and
the first terminal surface (42) and the second terminal surface (52) are exposed from the resin second surface (92).

### Clause 12.

The semiconductor device (A1) according to any one of clauses 1 to 11, wherein the semiconductor element (8) is mounted on the second lead (5).

Clause 13.

The semiconductor device (A11) according to any one of clauses 1 to 11, further comprising a fourth lead (7) on which the semiconductor element (8) is mounted.

### Clause 14.

The semiconductor device (A2) according to any one of clauses 1 to 13, further comprising a fifth terminal surface (55) located on the second side (y2) in the second direction (y) relative to the second terminal surface (52),
wherein the second conductive member (2) includes a portion extending from the second electrode (82) to the second side (y2) in the second direction (y), and is electrically connected to the fifth terminal surface (55).

### Clause 15.

The semiconductor device (A2) according to clause 14, wherein the second lead (5) includes the fifth terminal surface (55).

### Clause 16.

The semiconductor device (A1) according to clause 1, wherein the first conductive member (1) includes a first branch portion (11) and a first connecting portion (13),
the first branch portion (11) has a shape extending along the second direction (y), and is electrically bonded to the first electrode (81), and
the first connecting portion (13) is located on the first side (y1) in the second direction (y) relative to the first branch portion (11), and is electrically bonded to the first lead (4).

### Clause 17.

The semiconductor device (A1) according to clause 16, wherein the second conductive member (2) includes a second branch portion (21) and a second connecting portion (23),
the second branch portion (21) has a shape extending along the second direction (y), and is electrically bonded to the second electrode (82), and
the second connecting portion (23) is located on the first side (y1) in the second direction (y) relative to the second branch portion (21), and is electrically bonded to the second lead (5).

### Clause 18.

The semiconductor device (A1) according to any one of clauses 1 to 17, wherein the first electrode (81) is a drain electrode, and the second electrode (82) is a source electrode.

### Clause 19.

The semiconductor device (A1) according to any one of clauses 1 to 17, wherein the first electrode (81) is a source electrode, and the second electrode (82) is a drain electrode.

### Clause 20.

The semiconductor device (A1) according to any one of clauses 1 to 19, wherein the element body (80) contains GaN.

### Clause 21.

The semiconductor device (A1) according to any one of clauses 1 to 20, wherein the semiconductor element (8) includes a third electrode (83).

### Clause 22.

The semiconductor device (A1) according to any one of clauses 1 to 21, wherein each of first conductive member (1) and the second conductive member (2) is made of a metal plate.

### Clause 23.

The semiconductor device (A13) according to clause 1, wherein each of the first conductive member (1) and the second conductive member (2) is made of a wire.

### REFERENCE NUMERALS

A1, A11, A12, A2, A21: Semiconductor device 1: First conductive member
2: Second conductive member 3: Third conductive member
4: First lead 5: Second lead
5A: Fifth lead 6: Third lead
7: Fourth lead 8: Semiconductor element
9: Sealing resin 11: First branch portion
12: First main portion 13: First connecting portion
19: Conductive bonding material 21: Second branch portion
22: Second main portion 23: Second connecting portion
24: Third connecting portion 29: Conductive bonding material
41: First obverse surface 42: First terminal surface
43: First thick portion 44: First thin portion
51: Second obverse surface 52: Second terminal surface
53: Second thick portion 54: Second thin portion
55: Fifth terminal surface 56: Additional thick portion
57: Fifth obverse surface 61: Third obverse surface
62: Third terminal surface 63: Third thick portion
64: Third thin portion 71: Fourth obverse surface
72: Fourth terminal surface 73: Fourth thick portion
74: Fourth thin portion 80: Element body
81: First electrode 82: Second electrode
83: Third electrode 89: Bonding material
91: Resin first surface 92: Resin second surface
93: Resin third surface 94: Resin fourth surface
95: Resin fifth surface 96: Resin sixth surface
111: First bonding portion 112: First front end portion
113: First rear end portion 114: First root portion
121: First recess 122: First through-hole
131: Inclined portion 1311: Through-hole
132: Bonding portion 211: Second bonding portion
212: Second front end portion 213: Second rear end portion
214: Second root portion 221: Second recess
222: Second through-hole 223: Extending portion
x: Third direction y: Second direction
z: First direction

1. A semiconductor device comprising:
a semiconductor element including an element body, a first electrode located on a first side in a first direction relative to the element body, and a second electrode located on the first side in the first direction relative to the element body;
a first lead located on a first side in a second direction intersecting the first direction relative to the semiconductor element, the first lead including a first terminal surface;
a second lead including a second terminal surface located on a second side in the second direction relative to the first lead;
a first conductive member extending from the semiconductor element to the first side in the second direction, and electrically connecting the first electrode and the first lead;
a second conductive member extending from the semiconductor element to the first side in the second direction, and electrically connecting the second electrode and the second lead; and
a sealing resin covering the semiconductor element, the first conductive member, the second conductive member, and parts of the first lead and the second lead, while exposing the first terminal surface and the second terminal surface.

2. The semiconductor device according to claim 1, wherein the semiconductor element includes a plurality of the first electrodes and a plurality of the second electrodes, and
the plurality of first electrodes and the plurality of second electrodes are alternately arranged in a third direction intersecting the first direction and the second direction.

3. The semiconductor device according to claim 2, wherein the first conductive member includes a plurality of first branch portions and a first connecting portion,
each of the plurality of first branch portions has a shape extending along the second direction, and is electrically bonded to one of the plurality of first electrodes, and
the first connecting portion is located on the first side in the second direction relative to the plurality of first branch portions, and is electrically bonded to the first lead.

4. The semiconductor device according to claim 3, comprising a plurality of the second conductive members corresponding to the plurality of second electrodes, respectively,
wherein each of the plurality of second conductive members includes a second branch portion and a second connecting portion,
the second branch portion has a shape extending along the second direction, and is electrically bonded to one of the plurality of second electrodes, and
the second connecting portion is located on the first side in the second direction relative to the second branch portion, and is electrically bonded to the second lead.

5. The semiconductor device according to claim 4, wherein the plurality of first branch portions and the second branch portions of the plurality of second conductive members overlap as viewed in the third direction.

6. The semiconductor device according to claim 3, wherein the first connecting portion includes an inclined portion inclined relative to the first direction and the second direction.

7. The semiconductor device according to claim 6, wherein the inclined portion includes a through-hole.

8. The semiconductor device according to claim 3, wherein the first conductive member includes a first main portion interposed between the plurality of first branch portions and the first connecting portion, and extending in the third direction.

9. The semiconductor device according to claim 8, wherein the first main portion is located on the first side in the first direction relative to the plurality of first branch portions.

10. The semiconductor device according to claim 1, wherein the second conductive member is connected to a portion of the second lead that is located on the first side in the second direction relative to the semiconductor element.

11. The semiconductor device according to claim 1, wherein the sealing resin includes a resin first surface facing the first side in the first direction, and a resin second surface facing a second side in the first direction, and
the first terminal surface and the second terminal surface are exposed from the resin second surface.

12. The semiconductor device according to claim 1, wherein the semiconductor element is mounted on the second lead.

13. The semiconductor device according to claim 1, further comprising a fourth lead on which the semiconductor element is mounted.

14. The semiconductor device according to claim 1, further comprising a fifth terminal surface located on the second side in the second direction relative to the second terminal surface,
wherein the second conductive member includes a portion extending from the second electrode to the second side in the second direction, and is electrically connected to the fifth terminal surface.

15. The semiconductor device according to claim 14, wherein the second lead includes the fifth terminal surface.
